(19) United States
(12) Patent Application Publication
(10) Pub. No.: US 2024/0361271 A1
(43) Pub. Date: Oct. 31, 2024

(54) FLOATING GATE BIOSENSOR

(71) Applicant: International Business Machines Corporation, Armonk, NY (US)

(72) Inventors: Takashi Ando, Eastchester, NY (US); Sufi Zafar, Briarcliff Manor, NY (US); Alexander Reznicek, Troy, NY (US)

(21) Appl. No.: 18/306,678

(22) Filed: Apr. 25, 2023

(51) Int. Cl. G01N 27/414; H01L 29/66; H01L 29/78

(52) U.S. Cl. CPC G01N 27/4145; H01L 29/66825; H01L 29/785; H01L 2029/7858

(57) ABSTRACT

Embodiments are disclosed for a field effect transistor (FET) device. The FET device includes a semiconductor channel. Additionally, the FET device includes a first gate dielectric in contact with the semiconductor channel. Further, the FET device includes a metal-insulator-metal (MIM) structure. The MIM structure includes a liner comprising a first metal, an insulator, and a second metal. The first metal is in contact with the first gate dielectric. Additionally, the insulator is in contact with the first metal and the second metal. Further, the FET device includes a floating gate. The floating gate includes the first metal and an extension. Additionally, the extension is disposed to one side of the MIM structure, and includes a surface for sensing a sample in contact with the surface.

### BACKGROUND

The present disclosure relates to a biosensor, and more specifically, to a floating gate biosensor.

Biosensors can be electrical devices that sense specific conditions based on the concentration, or presence, of analytes in a medium. Analytes may include ions, proteins, deoxyribonucleic acid (DNA), and the like. For example, a biosensor can measure the concentration of sodium ions in human sweat to determine whether a person is dehydrated.

### SUMMARY

Embodiments are disclosed for a field effect transistor (FET) device. The FET device includes a semiconductor channel. Additionally, the FET device includes a first gate dielectric in contact with the semiconductor channel. Further, the FET device includes a metal-insulator-metal (MIM) structure. The MIM structure includes a liner comprising a first metal, an insulator, and a second metal. The first metal is in contact with the first gate dielectric. Additionally, the insulator is in contact with the first metal and the second metal. Further, the FET device includes a floating gate. The floating gate includes the first metal and an extension. Additionally, the extension is disposed to one side of the MIM structure, and includes a surface for sensing a sample in contact with the surface.

Embodiments are disclosed for a field effect transistor (FET) device. The FET device includes a semiconductor channel. Additionally, the FET device includes a first gate dielectric in contact with the semiconductor channel. Further, the FET device includes a metal-insulator-metal (MIM) structure. The MIM structure includes a liner comprising a first metal, an insulator, and a second metal. The first metal is in contact with the first gate dielectric. Additionally, the insulator is in contact with the first metal and the second metal. Further, the FET device includes a floating gate. The floating gate includes the first metal and an extension. Additionally, the extension is disposed to one side of the MIM structure, and includes a surface for sensing a sample in contact with the surface. Additionally, the FET device includes an additional layer covering the sensing surface. The additional layer includes a material selected from a group consisting of a conductive material and an insulating material.

Embodiments are disclosed for a field effect transistor (FET) device. The FET device includes a semiconductor channel. Additionally, the FET device includes a first gate dielectric in contact with the semiconductor channel. Further, the FET device includes a metal-insulator-metal (MIM) structure. The MIM structure includes a liner comprising a first metal, an insulator, and a second metal. The first metal is in contact with the first gate dielectric. Additionally, the insulator is in contact with the first metal and the second metal. Further, the FET device includes a floating gate. The floating gate includes the first metal and an extension. Additionally, the extension is disposed to one side of the MIM structure, and includes a surface for sensing a sample in contact with the surface. Further, the FET device includes a well having the sensing surface at a bottom and sides of the well. The well is configured to contain the sample.

Embodiments are disclosed for a field effect transistor (FET) device. The FET device includes a semiconductor channel. Additionally, the FET device includes a first gate dielectric in contact with the semiconductor channel. Further, the FET device includes a metal-insulator-metal (MIM) structure. The MIM structure includes a liner comprising a first metal, an insulator, and a second metal. The first metal is in contact with the first gate dielectric. Additionally, the insulator is in contact with the first metal and the second metal. Further, the FET device includes a floating gate. The floating gate includes the first metal and an extension. Additionally, the extension is disposed to one side of the MIM structure, and includes a surface for sensing a sample in contact with the surface. Further, the FET device includes a well having the sensing surface at a bottom. The well is configured to contain the sample. Additionally, the FET device includes an additional layer covering the sensing surface.

Embodiments are disclosed for a method for fabricating an FET device. The method includes forming a replacement gate by depositing a metal-insulator-metal structure in a recessed gate space. Additionally, the method includes recessing a spacer surrounding the replacement gate. Further, the method includes filling the recessed space with the first metal. Additionally, the method includes selectively recessing the filled recessed space. Further, the method includes filling the selectively recessed space with a spacer material. Additionally, the method includes forming a mask that covers the spacers, the replacement gate, and an interlayer dielectric (ILD) surrounding the spacers. Further, the method includes recessing the ILD. Additionally, the method includes forming a gate sensing surface by filling the recessed ILD space with the first metal.

### BRIEF DESCRIPTION OF THE DRAWINGS

FIG. 1A is a cross-sectional view of an example floating gate biosensor device and a testing solution, in accordance with some embodiments of the present disclosure.

FIG. 1B is a cross-sectional view of an example floating gate biosensor device and a testing solution, in accordance with some embodiments of the present disclosure.

FIG. 1C is a cross-sectional view of an example floating gate biosensor devices and a testing solution, in accordance with some embodiments of the present disclosure.

FIG. 2 is a fabrication view of an example floating gate biosensor device, in accordance with one or more embodiments of the disclosure.

FIG. 3 is a fabrication view of an example floating gate biosensor device, in accordance with one or more embodiments of the disclosure.

FIG. 4 is a fabrication view of an example floating gate biosensor device, in accordance with one or more embodiments of the disclosure.

FIG. 5 is a fabrication view of an example floating gate biosensor device, in accordance with one or more embodiments of the disclosure.

FIG. 6 is a fabrication view of an example floating gate biosensor device, in accordance with one or more embodiments of the disclosure.

FIG. 7 is a fabrication view of an example floating gate biosensor device, in accordance with one or more embodiments of the disclosure.

FIG. 8 is a fabrication view of an example floating gate biosensor device, in accordance with one or more embodiments of the disclosure.

FIG. 9 is a fabrication view of an example floating gate biosensor device, in accordance with one or more embodiments of the disclosure.

FIG. 10 is a fabrication view of an example floating gate biosensor device, in accordance with one or more embodiments of the disclosure.

FIG. 11 is a fabrication view of an example floating gate biosensor device, in accordance with one or more embodiments of the disclosure.

FIG. 12 is a fabrication view of an example floating gate biosensor device, in accordance with one or more embodiments of the disclosure.

FIG. 13 is a fabrication view of an example floating gate biosensor device, in accordance with one or more embodiments of the disclosure.

FIG. 14 is a process flow chart of a method for fabricating a floating gate biosensor device, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the embodiments described. On the contrary, the intention is to cover all modifications, equivalents, and alternatives falling within the spirit and scope of the present disclosure.

### DETAILED DESCRIPTION

As stated previously, a biosensor may measure analytes in a solution. While field effect transistors (FETs) may be useful in biosensors, such biosensors may include a reference electrode, which can be challenging to fabricate on a silicon device having FETs. More specifically, fabricating a silicon device with a reference electrode may increase the cost of manufacture, and the size of the footprint of the biosensor. Additionally, reference electrodes may be stored in a solution when not in use, which may not be suitable for silicon devices in wearable applications.

Accordingly, some embodiments of the present disclosure can provide a silicon biosensor device having an FET without a reference electrode. Further, removing the reference electrode reduces the footprint, the complexity of design, and the cost of producing a biosensor. In these ways, such embodiments may be useful as portable biosensors (e.g., used in wearable applications).

For the sake of brevity, conventional techniques related to semiconductor silicon device fabrication may or may not be described in detail herein. Moreover, the various tasks and process steps described herein can be incorporated into a more comprehensive procedure or process having additional steps or functionality not described in detail herein. Various steps in the manufacture of semiconductor silicon devices are well known and so, in the interest of brevity, many conventional steps will only be mentioned briefly herein or will be omitted entirely without providing the well-known process details.

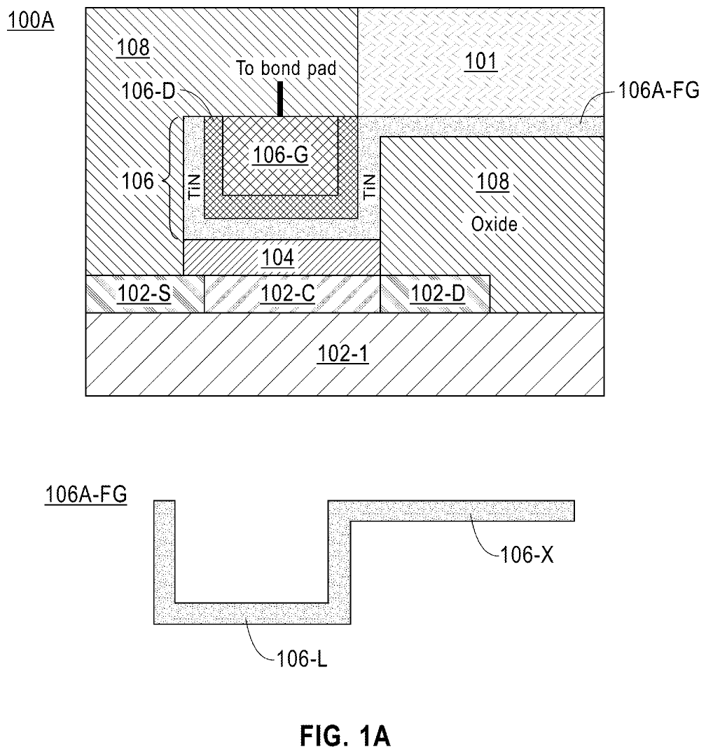

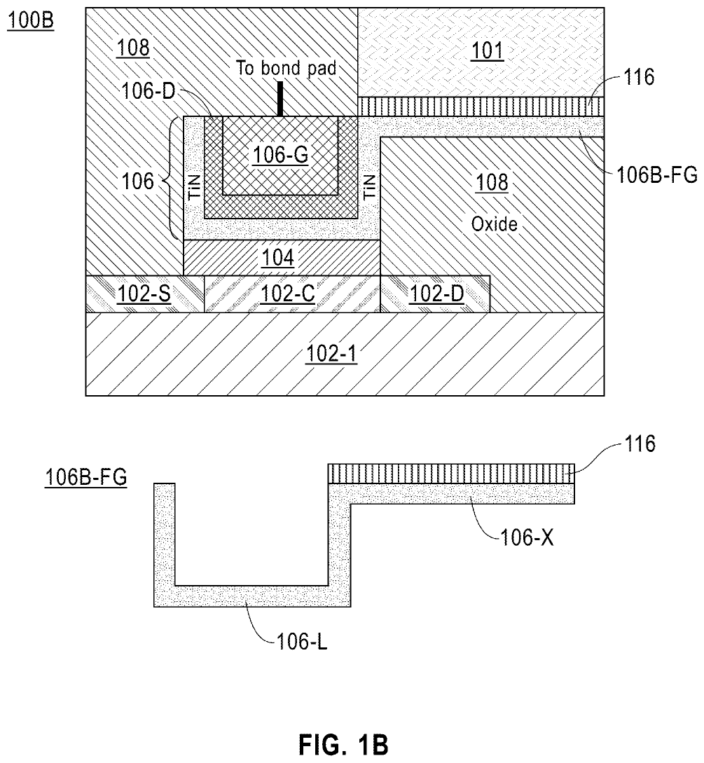

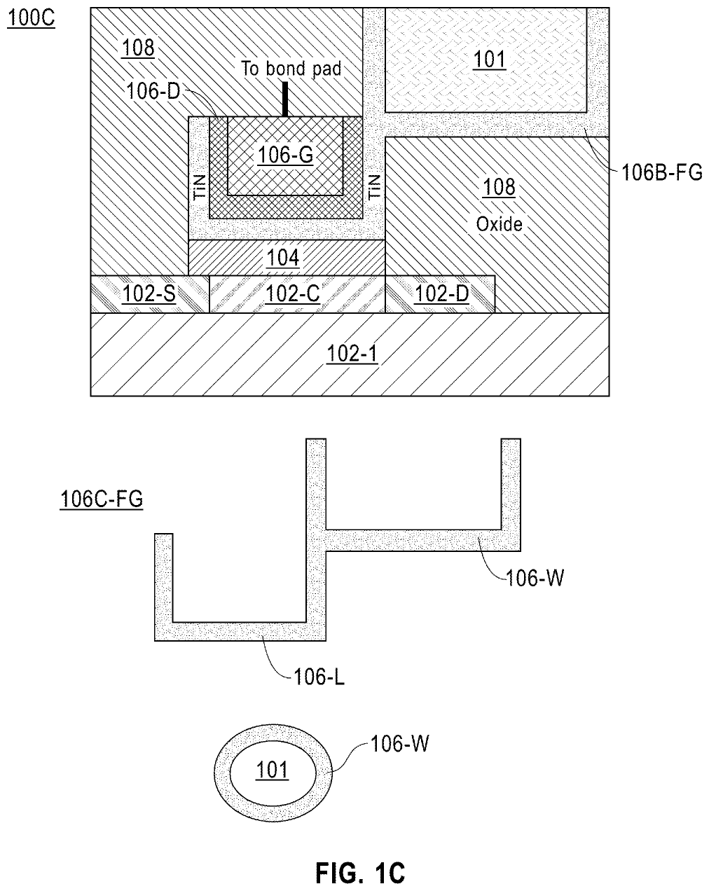

FIG. 1A is a cross-sectional view of an example floating gate biosensor device 100A, a test medium 101, and a floating gate 106A-FG, in accordance with some embodiments of the present disclosure. The test medium 101 may include aqueous and non-aqueous solutions; air; and solid mediums (e.g., soil, tissue); and the like, for testing. For example, an aqueous solution may include a preservative, water, and a target analyte for sensing. Further examples may include genetic material, sweat, blood, or any other medium having analytes suitable for biosensing.

The example floating gate biosensor device 100A includes an FET 102, a gate dielectric 104, replacement gate 106, oxide 108, and the floating gate 106A-FG. The FET 102 includes a silicon (Si) substrate 102-1, source 102-S, drain 102-D, and semiconductor channel 102-C. The channel 102-C can include nano-sheet materials which may be a semiconductor material that is conductive in a transistor, “on” state, or highly resistive in a transistor, “off” state. For example, channel 102-C may be silicon. Further, gate dielectric 104 may be composed of materials, such as, silicon oxide (SiO₂) or a bi-layer of SiO₂ and a high k material (e.g., k=7 or more). Accordingly, the materials for the gate dielectric 104 may differ based on the type of the FET 102 (e.g., N-type or P-type). Further, the conductivity of the semiconductor channel 102-C can be controlled by gate dielectric 104.

The replacement gate 106 may be a structure having a floating gate 106A-FG, gate dielectric 106-D, and control gate 106-G. The floating gate 106A-FG may include replacement gate liner 106-L and sensing surface 106-X. The replacement gate liner 106-L may extend to the sensing surface 106-X. The gate dielectric 106-D may be similar to the gate dielectric 104, but may have a different composition and/or different materials. For example, the gate dielectric 106-D may be composed of hafnium oxide (HfO₂). Further, the control gate 106-G may be in contact with a bond pad (not shown). The bond pad provides an interconnect to apply the voltage to actuate the example floating gate biosensor 100. Accordingly, when the target analyte in test medium 101 binds to the floating gate 106-FG, the surface potential changes. In operating the example floating gate biosensor 100, a drain current flowing between source 102-S and drain 102-D is the sensing signal. Change in the sensing signal detects the target analyte binding to the sensing surface 106-X in contact with test solution.

FIG. 1B is a cross-sectional view of an example floating gate biosensor device 100B, a test medium 101, and a floating gate 106B-FG, in accordance with some embodiments of the present disclosure. The example floating gate biosensor device 100B is similar to example floating gate biosensor device 100A. Further, the floating gate 106B-FG may be similar to the floating gate 106A-FG. However, the floating gate 106B-FG further includes an additional layer 116. The additional layer 116 may be disposed over the sensing surface 106-X, and thus in contact with the test medium 101. According to some embodiments of the present disclosure, the additional layer may be conducting (e.g., platinum [Pt], Pt silicide, graphene, gold) or insulating (e.g., SiO₂, HfO₂, Al₂O₃), varying based on the sensing application. With respect to an additional layer that is conducting, for example, thiol chemistry has been developed for functionalizing a gold sensing surface. With respect to an additional layer that is insulating, for example, the insulating layer may be useful for detecting proteins, nucleotide sequences, and viruses at ultralow concentrations.

FIG. 1C is a cross-sectional view of an example floating gate biosensor device 100C, a test medium 101, a floating gate 106C-FG, and a top view of a sensing surface 106-W, in accordance with some embodiments of the present disclosure. The example floating gate biosensor device 100C is similar to example floating gate biosensor device 100A. Further, the floating gate 106C-FG may be similar to the floating gate 106A-FG. However, the floating gate 106C-FG may include a replacement gate liner 106-L and sensing surface 106-W. The sensing surface 106-W may be a three-dimensional (3D) structure, forming a well that holds the test medium 101. In this way, such embodiments may increase the amount of sensing surface without increasing the footprint of the example floating gate biosensor device 100C. As shown, in the top view, the sensing surface 106-W can include an additional layer (not shown) that is similar to the additional layer 116 described with respect to FIG. 1B, and covering the sensing surface 106-W along the bottom and sides of the well.

Further, some embodiments of the present disclosure provide methods for fabricating biosensors, such as, the example floating gate biosensor devices 100A, 100B, 100C. Such embodiments can fabricate the example floating gate biosensor 100 on a silicon on insulator (SOI) wafer, or bulk wafers.

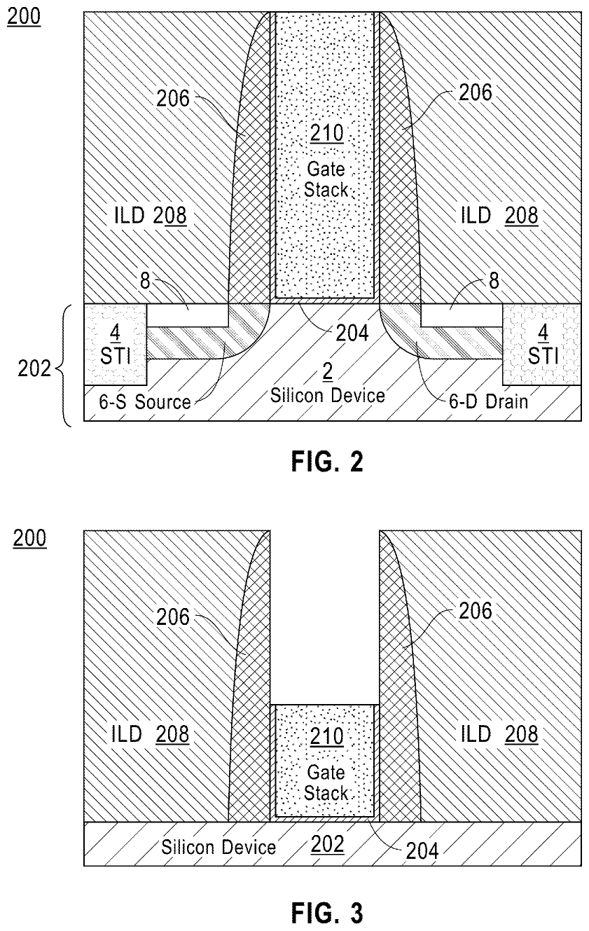

FIG. 2 is a cross-sectional view of the example floating gate biosensor 200 after initial fabrication operations, in accordance with some embodiments of the present disclosure. In the present fabrication stage, the example floating gate biosensor 200 includes a silicon device 202, gate dielectric 204, spacers 206, interlayer dielectric (ILD) 208, and gate stack 210. The ILD 208 is formed through a deposition process, and then followed with a planarization process that exposes the gate stack 210. The spacers 206 may be formed of dielectric materials, such as such as silicon nitride, SiBCN, SiNC, SIN, SiCO, SiNOC, or a combination thereof. The gate stack 210 may be composed of a work function setting metal (e.g. TiN) and a low resistivity metal (e.g. W or Al), and may be formed by replacement metal gate process. The silicon device 202, includes a silicon (Si) substrate 2, shallow trench isolation (STI) 4, source 6-S, drain 6-D, and silicide 8. The STI 4 may isolate neighboring devices from each other. The silicide 8 may provide contacts to the source 6-S and drain 6-D. It is noted that while the figures depict a planar device, the method of fabrication is also applicable to nanosheet and FinFET devices.

FIG. 3 is a cross-sectional view of the example floating gate biosensor 200 shown after exemplary fabrication operation(s), in accordance with some embodiments of the present disclosure. In the depicted fabrication stage, the gate stack 210 is recessed. Recessing involves removing a portion of the gate dielectric 204 and gate stack 210.

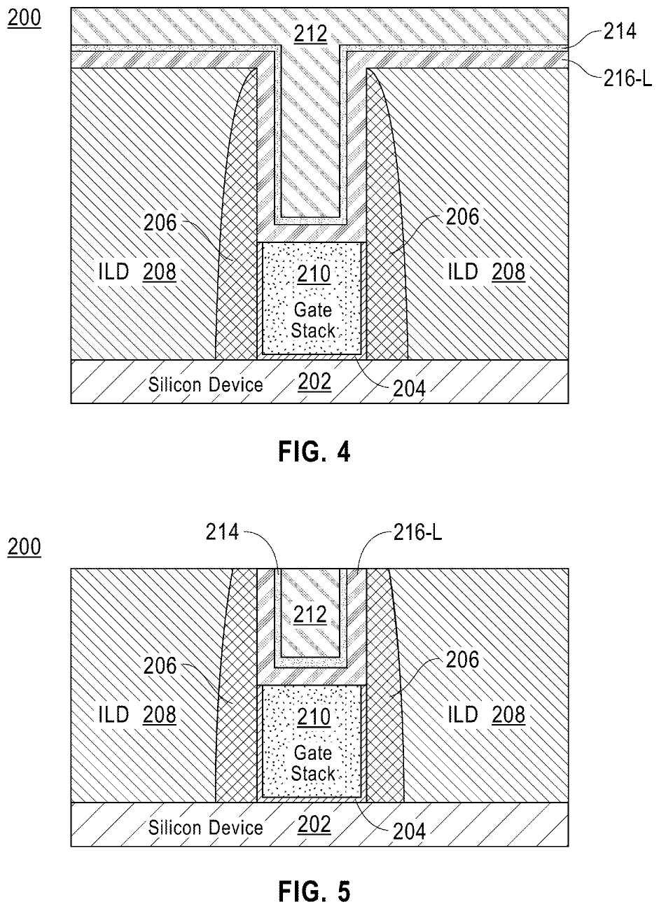

FIG. 4 is a cross-sectional view of the example floating gate biosensor 200 shown after exemplary fabrication operation(s), in accordance with some embodiments of the present disclosure. In the depicted fabrication stage, a metal insulator metal (MIM) structure is deposited into the recessed gate space (e.g., the space created by recessing the gate dielectric 204 and the gate stack 210). The MIM structure is similar to the replacement gate 106 described with respect to FIG. 1A, and includes control gate 212, dielectric 214, and replacement gate liner 216-L. The control gate 212 can be similar to the control gate 106-G. Additionally, the dielectric 214 can be similar to the dielectric 106-D. Further, the replacement gate liner 216-L can be similar to the replacement gate liner 106-L. According to some embodiments of the present disclosure, the two metals (e.g., the metal of control gate 212 and the metal of replacement gate liner 216-L) can be selectively etched. Further, the replacement gate liner 216-L may be thicker than the dielectric 214. In some embodiments, the replacement gate liner 216-L may be less than five nanometers, and the dielectric 214 can be less than one nanometer.

FIG. 5 is a cross-sectional view of the example floating gate biosensor 200 shown after exemplary fabrication operation(s), in accordance with some embodiments of the present disclosure. In the depicted fabrication stage, a chemical-mechanical planarization (CMP) process is performed on the structure. Performing the CMP process reduces the size of the gate stack 210 and further exposes the spacers 206.

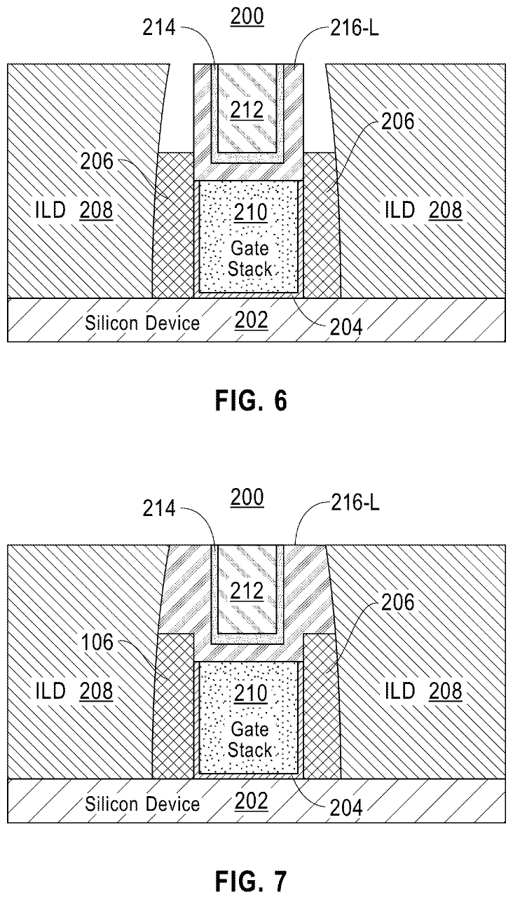

FIG. 6 is a cross-sectional view of the example floating gate biosensor 200 shown after exemplary fabrication operation(s), in accordance with some embodiments of the present disclosure. In the depicted fabrication stage, the spacers 206 are recessed. Recessing can involve reactive ion etching and/or wet etching of the spacers 206.

FIG. 7 is a cross-sectional view of the example floating gate biosensor 200 shown after exemplary fabrication operation(s), in accordance with some embodiments of the present disclosure. In the depicted fabrication stage, a metal fill is performed in the space created by recessing the spacers 206. The metal can be the same composition of the replacement gate liner 216-L, and thus forms part of the replacement gate liner 216-L.

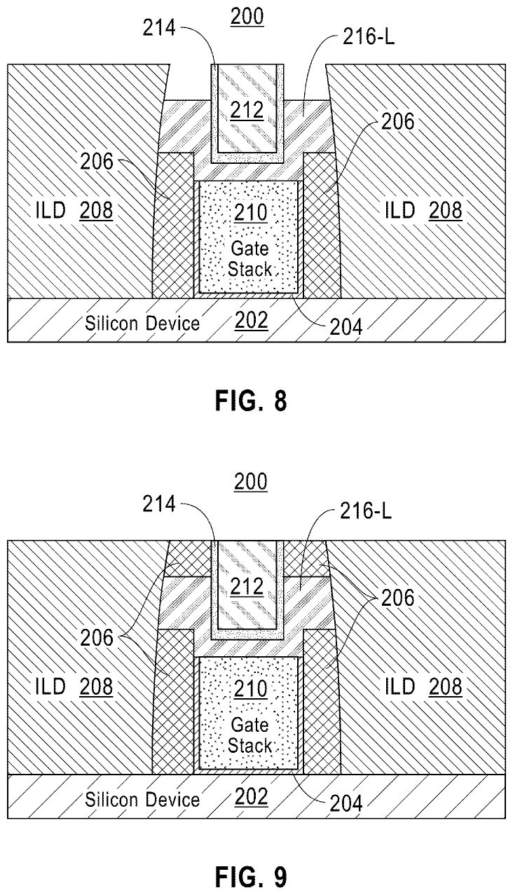

FIG. 8 is a cross-sectional view of the example floating gate biosensor 200 shown after exemplary fabrication operation(s), in accordance with some embodiments of the present disclosure. In the depicted fabrication stage, the replacement gate liner 216-L is selectively recessed. Selectively recessing the replacement gate liner 216-L can involve a chemical etching process that affects the replacement gate liner 216-L, but not the dielectric 214 and the control gate 216-L.

FIG. 9 is a cross-sectional view of the example floating gate biosensor 200 shown after exemplary fabrication operation(s), in accordance with some embodiments of the present disclosure. In the depicted fabrication stage, the recessed liner space is filed with spacer material. Filling this space with spacer material can involve a deposition process, followed by a CMP process.

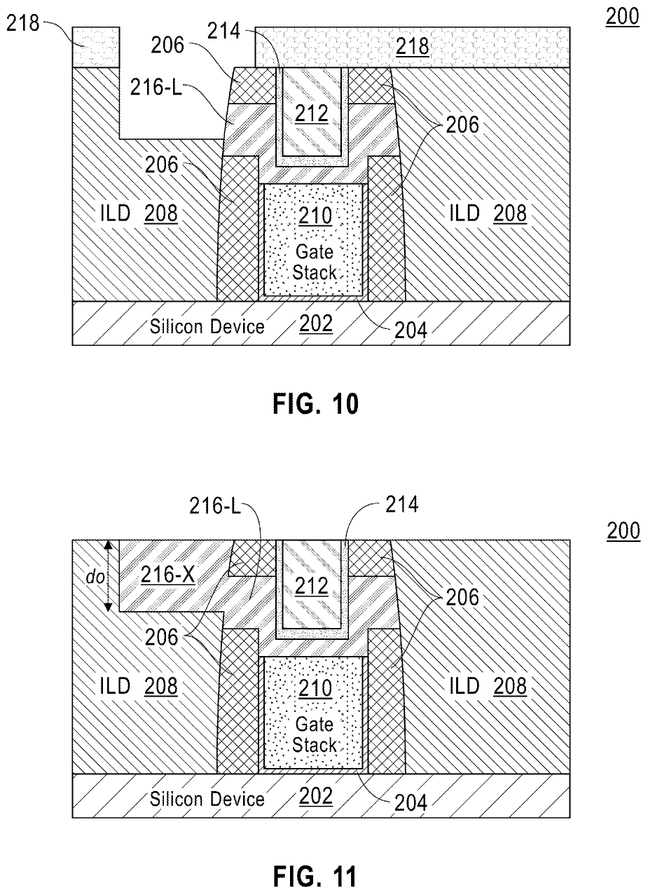

FIG. 10 is a cross-sectional view of the example floating gate biosensor 200 shown after exemplary fabrication operation(s), in accordance with some embodiments of the present disclosure. In the depicted fabrication stage, a mask 218 is deposited and patterned on the structure, and the ILD 208 is recessed to form a recessed ILD space.

FIG. 11 is a cross-sectional view of the example floating gate biosensor 200 shown after exemplary fabrication operation(s), in accordance with some embodiments of the present disclosure. In the depicted fabrication stage, sensing surface is formed. Forming the sensing surface can involve removing the mask 218, filing the recessed ILD space with a metal, and performing a CMP process on the structure. The metal can be the same composition of the replacement gate liner 216-L, and forms the sensing surface 216-X of floating gate 216. According to some embodiments of the present disclosure, the sensing surface 216-X is thicker than the thickness of the replacement gate liner 216-L. In this way, the sensing surface 216-X can reduce resistance. Further, in the depicted fabrication stage, the example floating gate biosensor 200 is similar to the example floating gate biosensor device 100A, described with respect to FIG. 1A.

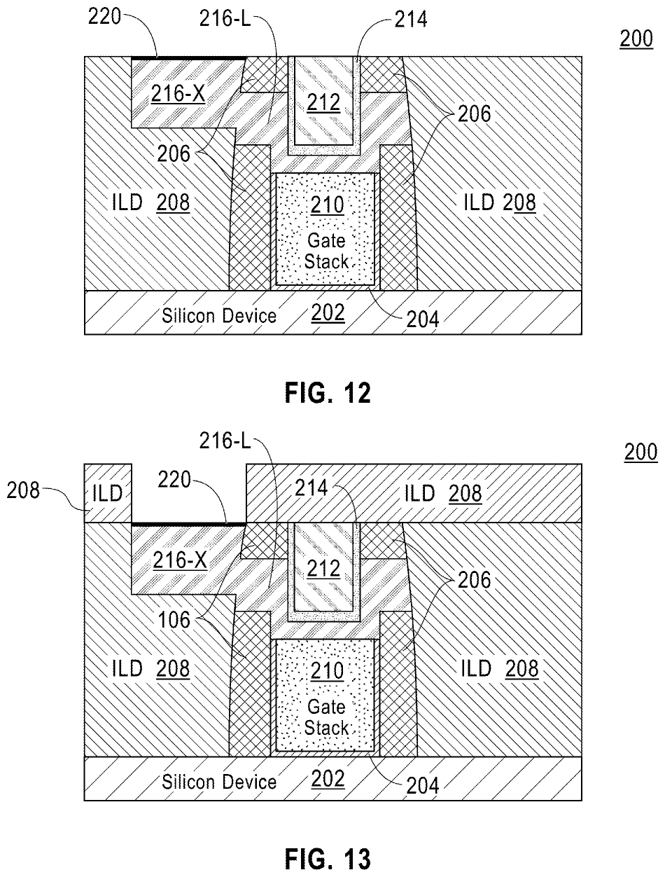

FIG. 12 is a cross-sectional view of the example floating gate biosensor 200 shown after exemplary fabrication operation(s), in accordance with some embodiments of the present disclosure. In the depicted fabrication stage, the floating gate surface is coated with a sensing surface 220. The sensing surface 220 can be similar to the additional layer 116 described with respect to FIG. 1B. As stated previously, the sensing surface 220 can be conducting or insulating. Further, in the depicted fabrication stage, the example floating gate biosensor 200 is similar to the example floating gate biosensor device 100B, described with respect to FIG. 1B.

FIG. 13 is a cross-sectional view of the example floating gate biosensor 200 shown after exemplary fabrication operation(s), in accordance with some embodiments of the present disclosure. In the depicted fabrication stage, a sensing reservoir can be formed. Forming the sensing reservoir can involve depositing additional ILD 208 on the structure, and recessing a portion of the ILD to form the sensing reservoir and expose the sensing surface 220. Further, in the depicted fabrication stage, the example floating gate biosensor 200 is similar to the example floating gate biosensor device 100C, described with respect to FIG. 1C.

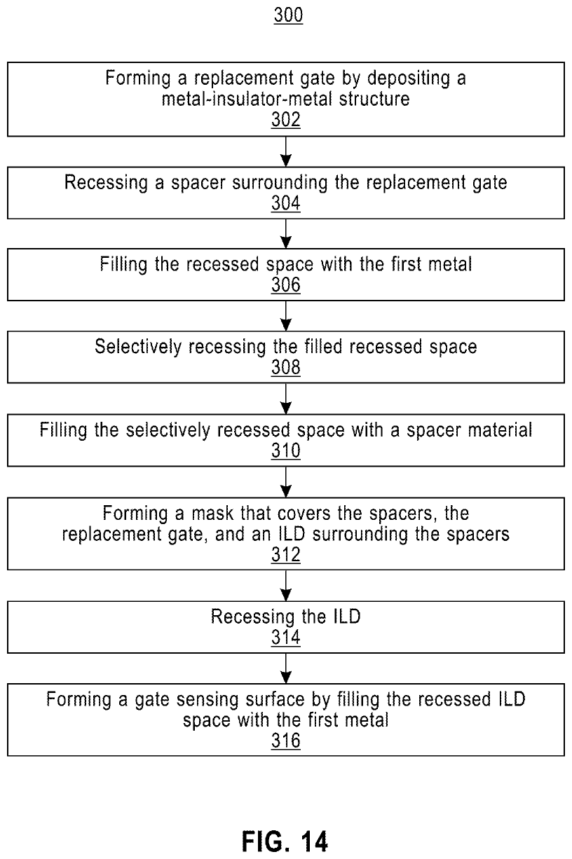

FIG. 14 is a process flow chart of a method 300 for fabricating a floating gate biosensor device, in accordance with some embodiments of the present disclosure. The depicted fabrication operations of method 300 are illustrated and described above with reference to one or more of FIG. 2 through FIG. 13 of the drawings. The method 300 depicted herein is exemplary. There can be many variations to the diagram or operations described therein without departing from the spirit of the embodiments. For instance, the operations can be performed in a differing order, or operations can be added, deleted, or modified.

At block 302, method 300 may begin with forming a replacement gate by depositing a metal-insulator metal structure in a recessed gate space. As stated previously, the MIM structure is similar to the replacement gate 106 described with respect to FIG. 1A, and includes control gate 212, dielectric 214, and titanium nitride (TiN) liner 216-L, described with respect to FIGS. 2-13. According to some embodiments of the present disclosure, the two metals (e.g., control gate 212 and replacement gate liner 216-L) can be selectively etched. Further, the replacement gate liner 216-L may be thicker than the dielectric 214.

At block 304, method 300 may further continue with recessing a spacer surrounding the replacement gate. As stated previously, recessing involves removing a portion of the gate dielectric 204 and gate stack 210.

At block 306, method 300 may further continue with filling the recessed space with a first metal. Filling the recessed space involves performing a metal fill in the space created by recessing the spacers 206. The metal can be the same composition of the replacement gate liner 216-L, and thus forms part of the replacement gate liner 216-L.

At block 308, method 300 may further continue with selectively recessing the filled recessed space. Selectively recessing the replacement gate liner 216-L can involve a chemical etching process that affects the replacement gate liner 216-L, but not the dielectric 214 and the control gate 216-L.

At block 310, method 300 may further continue with filling the selectively recessed space with a spacer material. Filling this space with spacer material can involve a deposition process, followed by a CMP process.

At block 312, method 300 may further continue with forming a mask (e.g., mask 218) the covers the spacers, the replacement gate, and an ILD surrounding the spacers. The mask 218 is deposited and patterned on the structure, and the ILD 208 is recessed.

At block 314, method 300 may further continue with recessing the ILD. Recessing the ILD can involve removing a portion of the ILD 208.

At block 316, method 300 may further continue with forming a gate sensing surface. Forming the sensing surface can involve removing the mask 218, filing the recessed ILD space with the first metal, and performing a CMP process on the structure. According to some embodiments of the present disclosure, the sensing surface 216-X is thicker than the thickness of the replacement gate liner 216-L. In this way, the sensing surface 216-X can reduce resistance. Further, in the depicted fabrication stage, the example floating gate biosensor 200 is similar to the example floating gate biosensor device 100A, described with respect to FIG. 1A.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A field effect transistor (FET) device comprising:
a FET comprising a semiconductor channel;
a first gate dielectric in contact with the semiconductor channel;
a metal-insulator-metal (MIM) structure comprising:
a liner comprising a first metal, wherein the first metal is in contact with the first gate dielectric;
an insulator in contact with the first metal; and
a second metal in contact with the insulator; and
a floating gate comprising the first metal and an extension, wherein the extension is disposed to one side of the MIM structure, wherein the extension comprises a surface for sensing a sample in contact with the surface.

2. The FET device of claim 1, further comprising an additional layer covering the sensing surface.

3. The FET device of claim 2, wherein the additional layer comprises a conductive material.

4. The FET device of claim 2, wherein the additional layer comprises an insulating material.

5. The FET device of claim 1, further comprising a well having the sensing surface at a bottom and sides of the well, and wherein the well is configured to contain the sample.

6. The FET device of claim 1, wherein the FET comprises a nanosheet device.

7. The FET device of claim 1, wherein the FET comprises a planar device.

8. The FET device of claim 1, wherein the FET comprises a FinFET device.

9. The FET device of claim 1, wherein the FET device comprises a silicon on insulator device.

10. The FET device of claim 1, wherein the semiconductor channel comprises a silicon channel.

11. A field effect transistor (FET) device comprising:
a FET comprising a semiconductor channel;
a first gate dielectric in contact with the semiconductor channel;
a metal-insulator-metal (MIM) structure comprising:
a liner comprising a first metal, wherein the first metal is in contact with the first gate dielectric;
an insulator in contact with the first metal; and
a second metal in contact with the insulator;
a floating gate comprising the first metal and an extension, wherein the extension is disposed to one side of the MIM structure, wherein the extension comprises a surface for sensing a sample in contact with the surface; and
an additional layer covering the sensing surface, wherein the additional layer comprises a material selected from a group consisting of a conductive material and an insulating material.

12. The FET device of claim 11, further comprising a well having the sensing surface at a bottom and sides of the well, wherein the well is configured to contain the sample.

13. The FET device of claim 11, wherein the FET comprises a nanosheet device.

14. The FET device of claim 11, wherein the FET comprises a planar device.

15. The FET device of claim 11, wherein the FET comprises a FinFET device.

16. The FET device of claim 11, wherein the FET device comprises a silicon on insulator device.

17. The FET device of claim 11, wherein the semiconductor channel comprises a silicon channel.

18. A field effect transistor (FET) device comprising:
a FET comprising a semiconductor channel;
a first gate dielectric in contact with the semiconductor channel;
a metal-insulator-metal (MIM) structure comprising:
a liner comprising a first metal, wherein the first metal is in contact with the first gate dielectric;
an insulator in contact with the first metal; and
a second metal in contact with the insulator;
a floating gate comprising the first metal and an extension, wherein the extension is disposed to one side of the MIM structure, wherein the extension comprises a surface for sensing a sample in contact with the surface; and
a well having the sensing surface at a bottom and sides of the well, and wherein the well is configured to contain the sample.

19. The FET device of claim 1, further comprising an additional layer covering the sensing surface, wherein the additional layer comprises a material selected from a group consisting of a conductive material and an insulating material.

20. The FET device of claim 18, wherein the semiconductor channel comprises a silicon channel.

21. A field effect transistor (FET) device comprising:
a FET comprising a semiconductor channel;
a first gate dielectric in contact with the semiconductor channel;
a metal-insulator-metal (MIM) structure comprising:
a liner comprising a first metal, wherein the first metal is in contact with the first gate dielectric;
an insulator in contact with the first metal; and
a second metal in contact with the insulator;
a floating gate comprising the first metal and an extension, wherein the extension is disposed to one side of the MIM structure, wherein the extension comprises a surface for sensing a sample in contact with the surface;
a well having the sensing surface at a bottom, and wherein the well is configured to contain the sample; and
an additional layer covering the sensing surface.

22. A method for fabricating an FET device, comprising:
forming a replacement gate by depositing a metal-insulator-metal structure in a recessed gate space;
recessing a spacer surrounding the replacement gate;
filling the recessed space with a first metal;
selectively recessing the filled recessed space;
filling the selectively recessed space with a spacer material;
forming a mask that covers the spacers, the replacement gate, and an interlayer dielectric (ILD) surrounding the spacers;
recessing the ILD; and
forming a gate sensing surface by filling the recessed ILD space with the first metal.

23. The method of claim 22, further comprising coating the gate sensing surface with an additional layer material.

24. The method of claim 23, wherein the additional layer material comprises a conducting material.

25. The method of claim 23, wherein the additional layer material comprises an insulating material.
